(19) United States
(12) Patent Application Publication
(10) Pub. No.: US 2020/0160918 A1
(43) Pub. Date: May 21, 2020

(54) MEMORY SYSTEM AND METHOD OF OPERATING THE SAME

(71) Applicant: SK hynix Inc., Gyeonggi-do (KR)

(72) Inventor: Eu Joon BYUN, Gyeonggi-do (KR)

(21) Appl. No.: 16/460,310

(22) Filed: Jul. 2, 2019

(30) Foreign Application Priority Data
Nov. 21, 2018 (KR) 10-2018-0144904

(51) Int. Cl. G11C 16/26; G06F 3/06; G06F 13/16

(52) U.S. Cl. CPC G11C 16/26; G06F 3/061; G06F 13/1668; G06F 3/0655; G06F 3/0679

(57) ABSTRACT

A memory system includes a host configured to transmit a read command and an address and request a read operation; a controller configured to generate an internal command corresponding to the read operation in response to the read command and the address, and generate an accumulated read count of the address on which the read operation has been completed; and a memory device configured to perform the read operation in response to the internal command and transmit data read by performing the read operation to the controller. The controller may receive the read data from the memory device, temporarily store the read data, transmit the read data to the host, and generate an address list including information about the address when the accumulated read count of the address is greater than or equal to a set count or more.

### CROSS-REFERENCE TO RELATED APPLICATION

The present application claims priority under 35 U.S.C. § 119(a) to Korean patent application number 10-2018-0144904, filed on Nov. 21, 2018, the entire disclosure of which is incorporated herein by reference in its entirety.

### BACKGROUND

### Field of Invention

Various embodiments of the present disclosure generally relate to an electronic device, and more particularly, to a memory system and a method of operating the memory system.

### Description of Related Art

Recently, the paradigm for the computer environment has is transitioned to ubiquitous computing so that computer systems can be used anytime and anywhere. As a result, the use of portable electronic devices such as mobile phones, digital cameras, and notebook computers has rapidly increased. In general, such portable electronic devices use a memory system which employs a memory device, in other words, use a data storage device. The data storage device is used as a main memory device or an auxiliary memory device of the portable electronic devices.

A data storage device using a memory device provides advantages in that, since there is no mechanical driving part, stability and durability are excellent, information access speed is increased, and power consumption is reduced. In the context of a memory system, data storage devices having such advantages include a universal serial bus (USB) memory device, a memory card having various interfaces, and a solid state drive (SSD).

Memory devices are generally classified as either volatile memory devices or nonvolatile memory devices.

A nonvolatile memory device, although having comparatively low read and write speeds, may retain stored data even when power supply is interrupted. Therefore, a nonvolatile memory device is used for storing data which is required to be retained regardless of whether or not power is supplied. Representative examples of a nonvolatile memory device include a read-only memory (ROM), a mask ROM (MROM), a programmable ROM (PROM), an erasable programmable ROM (EPROM), an electrically erasable programmable ROM (EEPROM), a flash memory, a phase-change random access memory (PRAM), a magnetic RAM (MRAM), a resistive RAM (RRAM), and a ferroelectric RAM (FRAM). The flash memory may be a NOR type memory or a NAND type memory.

### SUMMARY

Various embodiments of the present disclosure are directed to a memory system which is improved in efficiency by restraining a read reclaim operation, and a method of operating the memory system.

An embodiment of the present disclosure may provide for a memory system including: a host configured to transmit a read command and an address and request a read operation; a controller configured to generate an internal command corresponding to the read operation in response to the read command and the address, and generate an accumulated read count of the address on which the read operation has been completed; and a memory device configured to perform the read operation in response to the internal command and transmit data read by performing the read operation to the controller, wherein the controller receives the read data from the memory device, temporarily stores the read data, and then transmits the read data to the host, and generates an address list including information about the address when the accumulated read count of the address s greater than or equal to a set count.

An embodiment of the present disclosure may provide for a memory system including: a controller configured to generate an internal command corresponding to a read operation in response to a read request and an address that are received from a host, and generate an accumulated read count of the address on which the read operation has been completed; and a memory device configured to perform the read operation in response to the internal command and transmit data read by performing the read operation to the controller, wherein the controller controls the memory device such that, when the accumulated read count of the address is greater than or equal to a first set count, the read data received from the memory device is stored in a new memory block of the memory device.

An embodiment of the present disclosure may provide for a method of operating a memory system, including: receiving a read command and an address from a host; performing a read operation of a memory device in response to the read command and the address; temporarily storing data read as a result of the read operation in a controller, and transmitting the read data to the host; generating an accumulated read count of the address, and comparing the accumulated read count with a first set count; and generating, when the accumulated read count is greater than or equal to the first set count as a result of the comparing, an address list including information about the address, and transmitting the address list to the host.

An embodiment of the present disclosure may provide for a memory system including: a host configured to provide a read request and a first logical address for user data; and a memory system configured to: read the user data from a storage region corresponding to the first logical address in response to the read request; and provide information on the first logical address when a cumulative read count corresponding to the first logical address reaches a threshold value, wherein the host further provides a write request and a second logical address for the user data in response to the information, and wherein the memory system further stores the user data in a storage region corresponding to the second logical address in response to the write request.

An embodiment of the present disclosure may provide for a method of operating a memory system, including: providing, by a host, a read request and a first logical address for user data; reading, by a memory system, the user data from a storage region corresponding to the first logical address in response to the read request; providing, by the memory system, information on the first logical address when a cumulative read count corresponding to the first logical address reaches a threshold value; providing, by the host, a write request and a second logical address for the user data in response to the information; and storing, by the memory system, the user data in a storage region corresponding to the second logical address in response to the write request.

### BRIEF DESCRIPTION OF THE DRAWINGS

FIG. 1 is a block diagram illustrating a memory system in accordance with an embodiment of the present disclosure.

FIG. 2 is a block diagram illustrating a configuration of a controller of FIG. 1 in accordance with an embodiment of the present disclosure.

FIG. 3 is a diagram illustrating a semiconductor memory of FIG. 1 in accordance with an embodiment of the present disclosure.

FIG. 4 is a diagram illustrating an exemplary memory block of FIG. 3.

FIG. 5 is a diagram illustrating a memory block having a three-dimensional structure in accordance with an embodiment of the present disclosure.

FIG. 6 is a diagram illustrating a memory block having a three-dimensional structure in accordance with another embodiment of the present disclosure.

FIG. 7 is a flowchart illustrating an operation of the memory system in accordance with an embodiment of the present disclosure.

FIG. 8 is a block diagram illustrating a controller of FIG. 1 in accordance with an embodiment of the present disclosure.

FIG. 9 is a diagram illustrating a memory system in accordance with an embodiment of the present disclosure.

FIG. 10 is a diagram illustrating a memory system in accordance with an embodiment of the present disclosure.

FIG. 11 is a diagram illustrating a memory system in accordance with an embodiment of the present disclosure.

FIG. 12 is a diagram illustrating a memory system in accordance with an embodiment of the present disclosure.

### DETAILED DESCRIPTION

Specific structural and functional description provided herein is directed to embodiments of the present disclosure. Such description, however, is not intended to limit the scope of the invention to the disclosed embodiments, as the invention may be implemented in various forms, which may be modifications or variations of any of the disclosed embodiments.

Moreover, while the disclosed embodiments are described in detail, the present invention is not limited to specific details. Rather, the present invention covers all covering modifications, equivalents and alternatives of the disclosed embodiments that fall within the spirit and scope of the present disclosure.

It will be understood that, although the terms “first”, “second”, etc. may be used herein to identify various elements, these elements are not limited by these terms. These terms are only used to distinguish one element from another element that otherwise have the same or similar names. For example, a first element in one instance could be termed a second element in another instance without departing from the teachings of the present disclosure.

It will be understood that when an element is referred to as being “coupled” or “connected” to another element, it can be directly coupled or connected to the other element or one or more intervening elements may be present therebetween. In contrast, it should be understood that when an element is referred to as being “directly coupled” or “directly connected” to another element, there are no intervening elements present. Other expressions that explain the relationship between elements, such as “between”, “directly between”, “adjacent to” or directly adjacent 1244o13192” should be construed in the same way.

The terminology used herein is for the purpose of describing particular embodiments only and is not intended to be limiting. In the present disclosure, the singular forms are intended to include the plural forms and vice versa, unless the context clearly indicates otherwise. It will be further understood that the terms “comprise”, “include”, “have”, etc.

when used in this specification, specify the presence of stated features, integers, steps, operations, elements, components, and/or combinations of them but do not preclude the presence or addition of one or more other features, integers, steps, operations, elements, components, and/or combinations thereof.

Unless otherwise defined, all terms including technical and scientific terms used herein have the same meaning as commonly understood by one of ordinary skill in the art to which the present disclosure belongs. It will be further understood that terms used herein should be interpreted as having a meaning that is consistent with their meaning in the context of this specification and the relevant art and not be interpreted in an idealized or overly formal sense unless expressly so defined herein.

Detailed description of functions and structures well known to those skilled in the art is omitted to avoid obscuring the subject matter of the present disclosure. This aims to omit unnecessary description so as to make the subject matter of the present disclosure clear.

Various embodiments of the present disclosure are described more fully below with reference to the accompanying drawings, in which preferred embodiments of the present disclosure are shown, so that those skilled in the art can easily carry out and practice the present invention. Throughout the specification, reference to “an embodiment,” “another embodiment” or the like is not necessarily to only one embodiment, and different references to any such phrase are not necessarily to the same embodiment(s).

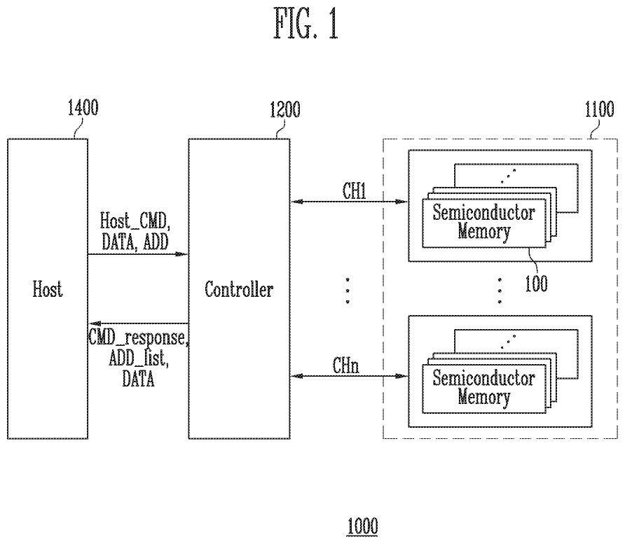

FIG. 1 is a block diagram illustrating a memory system 1000 in accordance with an embodiment of the present disclosure.

Referring to FIG. 1, the memory system 1000 may include a memory device 1100, a controller 1200, and a host 1400. The memory device 1100 may include a plurality of semiconductor memories 100. The plurality of semiconductor memories 100 may be divided into a plurality of groups. Although in the present embodiment the host 1400 has been illustrated and described as being included in the memory system 1000, in another embodiment the memory system 1000 may include only the controller 1200 and the memory device 1100, and the host 1400 may be disposed externally to the memory system 1000.

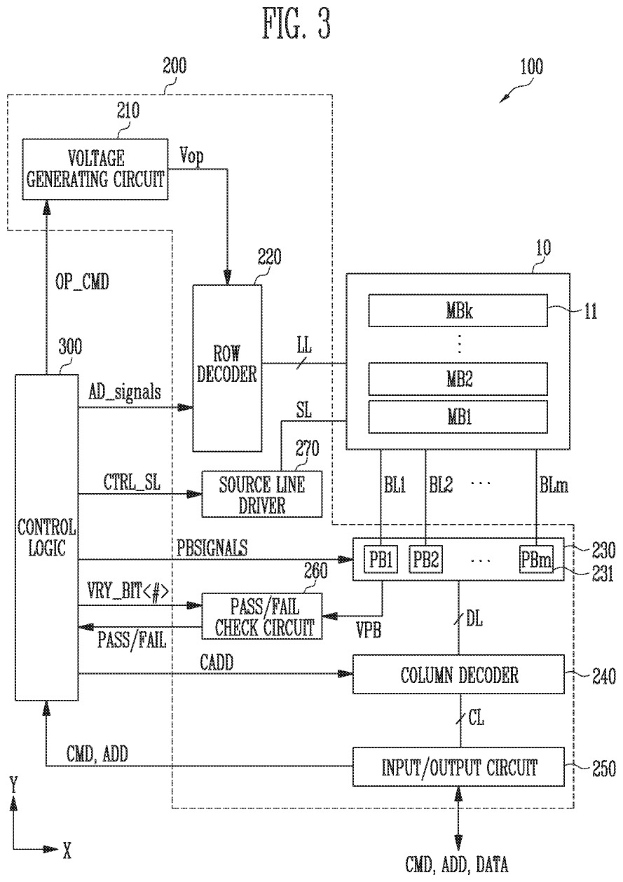

In FIG. 1, it is illustrated that the plurality of groups of the memory device 1100 communicate with the controller 1200 through first to n-th channels CH1 to CHn, respectively. Each semiconductor memory 100 will be described in detail later herein with reference to FIG. 3.

Each group may communicate with the controller 1200 through one common channel. The controller 1200 may control the plurality of semiconductor memories 100 of the memory device 1100 through the plurality of channels CH1 to CH1 to CHn.

The controller 1200 is coupled between the host 1400 and the memory device 1100. The controller 1200 may access the memory device 1100 in response to a request from the host 1400. For example, the controller 1200 may control a read operation, a write operation, an erase operation, or a background operation of the memory device 1100 in response to a host command Host_CMD received from the host 1400. The host 1400 may transmit an address ADD and data DATA along with the host command Host_CMD during a write operation, and may transmit an address ADD along with the host command Host_CMD during a read operation. The controller 1200 may transmit data DATA read during the read operation to the host 1400. The controller 1200 may provide an interface between the memory device 1100 and the host 1400. The controller 1200 may run firmware for controlling the memory device 1100.

When a host command Host_CMD corresponding to a read command is received from the host 1400, the controller 1200 may control the memory device 1100 to perform a read operation, and may count the number of times data associated with an address is requested to be read from the host 1400 to generate an accumulated read count for that address, which the controller 1200 may also manage. When the accumulated read count of the address is greater than or equal to a first set count, the corresponding address may be added to an address list ADD_list, and the updated address list ADD_list may be transmitted to the host 1400. The address list ADD_list may include addresses and information about such addresses, each of which has an accumulated read count greater than or equal to the first set count. When information about at least one address is added the address list ADD_list, the address list ADD_list may be transmitted to the host 1400. The address list ADD_list, along with a response signal CMD_response corresponding to the host command Host_CMD, may be transmitted to the host 1400. The response signal CMD_response may correspond to a host command Host_CMD for requesting the address list ADD_list, or correspond to a host command Host_CMD for requesting an operation such as a write operation or a read operation. In other words, the address list ADD_list may be transmitted to the host 1400, along with the response signal CMD_response corresponding to the host command Host_CMD for requesting the address list ADD_list, or along with the response signal CMD_response corresponding to the host command Host_CMD for requesting an operation such as a write operation or a read operation.

The controller 1200 may manage respective read counts of the plurality of memory blocks included in the memory device 1100, and control the memory device 1100 to perform a read reclaim operation on memory blocks, each of which has a read count that is greater than or equal to a second set count. The first set count and the second set count may differ from each other.

The host 1400 may include a portable electronic device such as a computer, a personal digital assistant (PDA), a portable multimedia player (PMP), an MP3 player, a camera, a camcorder, or a mobile phone. The host 1400 may use a host command Host_CMD to make a request for a write operation, a read operation, an erase operation, etc. of the memory system 1000. To perform a write operation of the memory device 1100, the host 1400 may transmit a host command Host_CMD corresponding to a write command, data DATA, and an address ADD to the controller 1200. To perform a read operation, the host 1400 may transmit a host command Host_CMD corresponding to a read command, and an address ADD to the controller 1200. Here, the address ADD may be a logical address of data.

The host 1400 may receive the address list ADD_list from the controller 1200. The address list ADD_list may be received along with a response signal CMD_response, or only the address list ADD_list may be received independently.

When the address list ADD_list is received, the host 1400 may request a write operation on the memory device 1100 based on the address information included in the address list ADD_list. In other words, an address of data corresponding to the address included in the address list ADD_list may be changed, and the changed address ADD and the host command Host_CMD corresponding to the write command may be transmitted to the controller 1200. The address included in the address list ADD_list has an accumulated read count that is determined to be greater than or equal to the first set count. Hence, the address included in the address list ADD_list is an address of a last requested read operation with reference to a time at which the host 1400 receives the address list ADD_list. Thus, data corresponding to the address included in the address list ADD_list may be data that has been received from the controller 1200 to the host 1400 as a result of a latest read operation, and data that has been temporarily stored in a read buffer of the controller 1200. Consequently, when a write operation of the memory device 1100 is requested based on the address information included in the address list ADD_list, the controller 1200 may be controlled such that data received from the controller 1200 is transmitted back to the controller 1200, or the write operation is performed using the data that has been temporarily stored in a read buffer of the controller 1200.

The controller 1200 and the memory device 1100 may be integrated into a single semiconductor device. In an embodiment, the controller 1200 and the memory device 1100 may be integrated into a single semiconductor device to form a memory card, such as a personal computer memory card international association (PCMCIA), a compact flash card (CF), a smart media card (SM or SMC), a memory stick multimedia card (MMC, RS-MMC, or MMCmicro), a SD card (SD, miniSD, microSD, or SDHC), or a universal flash storage (UFS),

In another embodiment, the controller 1200 and the memory device 1100 may be integrated into a single semiconductor device to form a solid state drive (SSD). The SSD may include a storage device configured to store data in a semiconductor memory.

In an embodiment, the memory system 1000 may be provided as one of various elements of an electronic device, such as a computer, a ultra mobile PC (UMPC), a workstation, a net-book, a personal digital assistants (PDA), a portable computer, a web tablet, a wireless phone, a mobile phone, a smart phone, an e-book, a portable multimedia player (PMP), a game console, a navigation device, a black box, a digital camera, a 3-dimensional television, a digital audio recorder, a digital audio player, a digital picture recorder, a digital picture player, a digital video recorder, a digital video player, a device capable of transmitting/receiving information in an wireless environment, one of various devices for forming a home network, one of various electronic devices for forming a computer network, one of various electronic devices for forming a telematics network, an RFID device, one of various elements for forming a computing system, or the like.

In an embodiment, the memory device 1100 or the memory system 1000 may be embedded in various types of packages. For example, the memory device 1100 or the memory system 1000 may be packaged in a type, such as Package on Package (PoP), Ball grid arrays (BGAs), Chip scale packages (CSPs), Plastic Leaded Chip Carrier (PLCC), Plastic Dual In Line Package (PDIP), Die in Waffle Pack, Die in Wafer Form, Chip On Board (COB), Ceramic Dual In Line Package (CERDIP), Plastic Metric Quad Flat Pack (MQFP), Thin Quad Flatpack (TQFP), Small Outline (SOIC), Shrink Small Outline Package (SSOP), Thin Small Outline (TSOP), Thin Quad Flatpack (TQFP), System In Package (SIP), Multi Chip Package (MCP), Wafer-level Fabricated Package (WFP), or Wafer-Level Processed Stack Package (WSP).

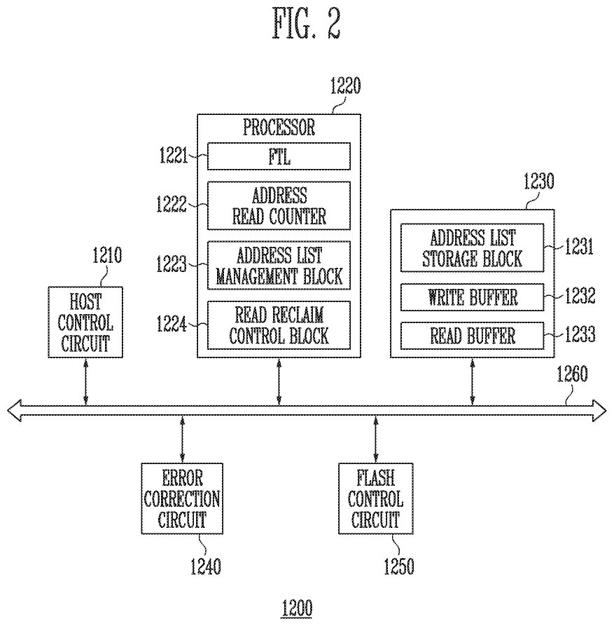

FIG. 2 is a diagram illustrating the controller 1200 of FIG. 1.

Referring to FIG. 2, the controller 1200 may include a host control circuit 1210, a processor 1220, a memory buffer circuit 1230, an error correction circuit 1240, a flash control circuit 1250, and a bus 1260.

The bus 1260 may provide a channel between the components of the controller 1200.

The host control circuit 1210 may control data transmission between the host 1400 of FIG. 1 and the memory buffer circuit 1230. In an embodiment, the host control circuit 1210 may control an operation of buffering data input from the host 1400 to the memory buffer circuit 1230. In an embodiment, the host control circuit 1210 may control an operation of outputting data buffered in the memory buffer circuit 1230 to the host 1400.

The host control circuit 1210 may transmit a host command and an address which are received from the host 1400 to the processor 1220, or may transmit the address list stored in the memory buffer circuit 1230 to the host 1400 under control of the processor 1220.

The host control circuit 1210 may include a host interface.

The processor 1220 may control the overall operation of the controller 1200 and perform a logical operation. The processor 1220 may communicate with the host 1400 of FIG. 1 through the host control circuit 1210, and communicate with the memory device 1100 of FIG. 1 through the flash control circuit 1250. The processor 1220 may control the operation of the memory system 1000 by using the memory buffer circuit 1230 as an operation memory, a cache memory, or a buffer memory. The processor 1220 may rearrange, based on priorities, a plurality of host commands received from the host 1400 and generate a command queue, and may control the flash control circuit 1250 based on the command queue. The processor 1220 may generate an accumulated read count of an address on which a read operation has been completed, and may generate an address list when the accumulated read count of the address is greater than or equal to the first set count, and store the address list in the memory buffer circuit 1230. Furthermore, the processor 1220 may count reads from the plurality of memory blocks in the memory device 1100 to generate respective read counts, one for each memory block, and control the flash control circuit 1250 to perform a read reclaim operation on a memory block the read count of which is greater than or equal to the second set count or more. When a host command corresponding to a write operation for data that has been read during a latest read operation and remains in the memory buffer circuit 1230 is received from the host 1400, the processor 1220 may control the flash control circuit 1230 to transmit such data to the memory device 1100 and program the data to the memory device 1100.

The processor 1220 may include a flash translation layer (FTL) 1221, an address read counter 1222, an address list management block 1223, and a read reclaim control block 1224.

The FTL 1221 may drive firmware. The firmware may be stored in an additional memory (not illustrated) directly coupled to the buffer memory 1230 or the processor 1220, or may be stored in a storage space defined in the processor 1220. During a write operation, the FTL 1221 may map a physical address corresponding to an address (e.g., a logical address) input from the host 1400 of FIG. 1. Furthermore, during a read operation, the FTL 1221 may check a physical address mapped to a logical address input from the host 1400.

The FTL 1221 may generate a command queue for controlling the flash control circuit 1250 in response to a host command received from the host 1400.

The address read counter 1222 may count the read of an address received from the host 1400 during a read operation and accumulate the counts. In other words, the address read counter 1222 may increase a previous accumulated read count of the address received from the host 1400 during the read operation by 1 as a result of the read operation associated with that address. The accumulated read count may be stored in the memory buffer circuit 1230.

When the accumulated read count of the address that is received from the host 1400 during the read operation is greater than or equal to the first set count, the address list management block 1223 may update information about the address on the address list and store the updated address list in the memory buffer circuit 1230.

The read reclaim control block 1224 may manage the respective read counts of the plurality of memory blocks in the semiconductor memories 100 of the memory device 1100 of FIG. 1, and control the flash control circuit 1250 to perform a read reclaim operation on a memory block, the read count of which is greater than or equal to the second set count, among the plurality of memory blocks.

The memory buffer circuit 1230 may be used as an operation memory, a cache memory, or a buffer memory of the processor 1220. The memory buffer circuit 1230 may store codes and commands to be executed by the processor 1220. The memory buffer circuit 1230 may store data to be processed by the processor 1220. The memory buffer circuit 1230 may store accumulated read counts of addresses and an address list generated by the processor 1220.

The memory buffer circuit 1230 may include an address list storage block 1231, a write buffer 1232, and a read buffer 1233. The address list storage block 1231 may store the accumulated read counts of the addresses and the address list generated by the processor 1220. The address list storage block 1231 may transmit the stored address list to the host 1400. The write buffer 1232 may temporarily store data received along with the write command from the host 1400, and then transmit the temporarily stored data to the memory device 1100 when the write command is transmitted to the memory device 1100. The read buffer 1233 may temporarily store data received from the memory device 1100 during a read operation, and then transmit the temporarily stored data to the host 1400. Furthermore, the read buffer 1233 may transmit the data remaining in the read buffer 1233 to the memory device 1100 when a write command for the temporarily stored data is received from the host 1400.

The memory buffer circuit 1230 may include a static RAM (SRAM) or a dynamic RAM (DRAM).

The error correction circuit 1240 may perform an error correction operation. The error correction circuit 1240 may perform an ECC (error correction code) encoding operation based on data to be written to the memory device 1100 of FIG. 1 through the flash control circuit 1250. ECC encoded data may be transmitted to the memory device 1100 through the flash control circuit 1250. The error correction circuit 1240 may perform an ECC decoding operation for data received from the memory device 1100 through the flash control circuit 1250. For example, the error correction circuit 1240 may be included in the flash control circuit 1250 as a component thereof.

The flash control circuit 1250 may generate and output an internal command far controlling the memory device 1100 in response to a command queue generated by the processor 1220. During a write operation, the flash control circuit 1250 may control an operation of transmitting and writing data buffered in the write buffer 1232 of the memory buffer circuit 1230 to the memory device 1100. In an embodiment, during a read operation, the flash control circuit 1250 may contral an operation of buffering, in the read buffer 1233 of the memory buffer circuit 1230, data read from the memory device 1100 in response to a command queue. Furthermore, the flash control circuit 1250 may control an operation of transmitting and writing data remaining in the write buffer 1233 to the memory device 1100 in response to a command queue generated by the processor 1220.

The flash control circuit 1250 may include a flash interface.

FIG. 3 is a diagram illustrating an example of the semiconductor memory 100 of FIG. 1.

Referring to FIG. 3, the semiconductor memory 100 may include a memory cell array 10 configured to store data. The semiconductor memory 100 may include a peripheral circuit 200 configured to perform a program operation for staring data in the memory cell array 10, a read operation for outputting the stored data, and an erase operation for erasing the stored data. The semiconductor memory 100 may include control logic 300 configured to control the peripheral circuit 200 under control of the controller (1200 of FIG. 1).

The memory cell array 10 may include a plurality of memory blocks MB1 to MBk (11; k is a positive integer). Local lines LL and bit lines BL1 to BLm (m is a positive integer) may be coupled to each of the memory blocks MB1 to MBk (11), For example, the local lines LL may include a first select line, a second select line, and a plurality of word lines arranged between the first and the second select lines. The local lines LL may include dummy lines arranged between the first select line and the word lines and between the second select line and the word lines. Here, the first select line may be a source select line, and the second select line may be a drain select line. For example, the local lines LL may include word lines, drain and source select lines, and source lines SL. For example, the local lines LL may further include dummy lines. For example, the local lines LL may further include pipelines. The local lines LL may be coupled to each of the memory blocks MB1 to MBk (11). The bit lines BL1 to BLm may be coupled in common to the memory blocks MB1 to MBk (11). The memory blocks MB1 to MBk (11) may be embodied in a two- or three-dimensional structure. For example, in the memory blocks 11 having a two-dimensional structure, the memory cells may be arranged in a direction parallel to a substrate. For instance, in the memory blocks 11 having a three-dimensional structure, the memory cells may be stacked in a direction perpendicular to the substrate.

The peripheral circuit 200 may perform a program operation, a read operation, or an erase operation on a selected memory block 11 under control of the control logic 300. For instance, the peripheral circuit 200 may include a voltage generating circuit 210, a row decoder 220, a page buffer group 230, a column decoder 240, an input/output circuit 250, a pass/fail check circuit 260, and a source line driver 270.

The voltage generating circuit 210 may generate various operating voltages Vop to be used for a program operation, a read operation, and an erase operation in response to an operating signal OP_CMD. Furthermore, the voltage generating circuit 210 may selectively discharge the local lines LL in response to an operating signal OP_CMD. For example, the voltage generating circuit 210 may generate a program voltage, a verify voltage, a pass voltage, and a select transistor operating voltage under control of the control logic 300.

The row decoder 220 may transmit operating voltages Vop to local lines LL coupled to a selected memory block 11 in response to control signals AD_signals. For example, the row decoder 220 may selectively apply operating voltages (e.g., a program voltage, a verify voltage, and a pass voltage) generated by the voltage generating circuit 210 to the word lines among the local lines LL in response to the control signals AD_signals.

During a program voltage applying operation, in response to the control signals AD_signals, the row decoder 220 may apply a program voltage generated by the voltage generating circuit 210 to a selected word line of the local lines LL, and apply a pass voltage generated by the voltage generating circuit 210 to the other unselected word lines. During a read operation, in response to the control signals AD_signals, the row decoder 220 may apply a read voltage generated by the voltage generating circuit 210 to a selected word line of the local lines LL, and apply a pass voltage generated by the voltage generating circuit 210 to the other unselected word lines.

The page buffer group 230 may include a plurality of page buffers PB1 to PBm (231) coupled to the bit lines BL1 to BLm. The page buffers PB1 to PBm (231) may operate in response to page buffer control signals PBSIGNALS. For instance, the page buffers PB1 to PBm (231) may temporarily store data to be programmed during a program operation, or sense voltages or currents of the bit lines BL1 to BLm during a read or verify operation.

The column decoder 240 may transmit data between the input/output circuit 250 and the page buffer group 230 in response to a column address CADD. For example, the column decoder 240 may exchange data with the page buffers 231 through data lines DL or exchange data with the input/output circuit 250 through column lines CL.

The input/output circuit 250 may transmit an internal command CMD or an address ADD received from the controller (1200 of FIG. 1) to the control logic 300, or exchange data with the column decoder 240.

During a read operation or a verify operation, the pass/fail check circuit 260 may generate a reference current in response to an enable bit VRY_BIT<#>, and may compare a sensing voltage VPB received from the page buffer group 230 with a reference voltage generated by the reference current and output a pass signal PASS or a fail signal FAIL.

The source line driver 270 may be coupled, through the source line SL, to the memory cells included in the memory cell array 10, and may control a voltage to be applied to the source line SL. The source line driver 270 may receive a source line control signal CTRL_SL from the control logic 300, and control a source line voltage to be applied to the source line SL based on the source line control signal CTRL_SL.

The control logic 300 may control the peripheral circuit 200 by outputting an operating signal OP_CMD, control signals AD_signals, page buffer control signals PBSIGNALS, and an enable bit VRY_BIT<#>in response to an internal command CMD and an address ADD. In addition, the control logic 300 may determine whether a target memory cell has passed a verification during a verify operation in response to a pass signal PASS or a fail signal FAIL.

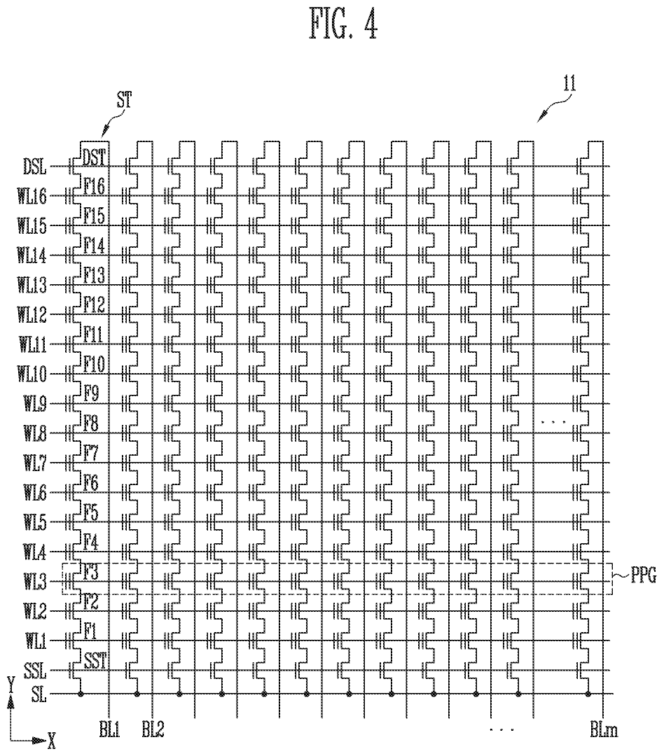

FIG. 4 is a diagram illustrating an exemplary structure of a memory block of FIG. 3.

Referring to FIG. 4, in the memory block 11, a plurality of word lines arranged parallel to each other may be coupled between a first select line and a second select line. Here, the first select line may be a source select line SSL, and the second select line may be a drain select line DSL. In more detail, the memory block 11 may include a plurality of strings ST coupled between the bit lines BL1 to BLm and the source line SL. The bit lines BL1 to BLm may be respectively coupled to the strings ST, and the source lines SL may be coupled in common to the strings ST. The strings ST may have the same configuration; therefore, the string ST that is coupled to the first bit line BL1 will be described in detail by way of example.

The string ST may include a source select transistor SST, a plurality of memory cells F1 to F16, and a drain select transistor DST which are coupled in series to each other between the source line SL and the first bit line BL1. At least one source select transistor SST and at least one drain select transistor DST may be included in each string ST, and a larger number of memory cells than the number of memory cells F1 to F16 shown in the drawing may be included in each string ST.

A source of the source select transistor SST may be coupled to the source line SL, and a drain of the drain select transistor DST may be coupled to the first bit line BL1. The memory cells F1 to F16 may be coupled in series between the source select transistor SST and the drain select transistor DST. Gates of the source select transistors SST included in different strings ST may be coupled to the source select line SSL, gates of the drain select transistors DST may be coupled to the drain select line DSL, and gates of the memory cells F1 to F16 may be coupled to the plurality of word lines WL1 to WL16. Among the memory cells included in different strings ST, a group of memory cells coupled to each word line may be referred to as a physical page PPG. Therefore, the number of physical pages PPG included in the memory block 11 may correspond to the number of word lines WL1 to WL16.

Each memory cell may store 1-bit data. This memory cell is typically called a single level cell (SLC). In this case, each physical page PPG may store data of a singe logical page LPG. Data of each logical page LPG may include data bits corresponding to the number of cells included in a single physical page PPG. Each memory cell may store 2-or more-bit data. This memory cell is typically called a multi-level cell (MLC). In this case, each physical page PPG may store data of two or more logical pages LPG.

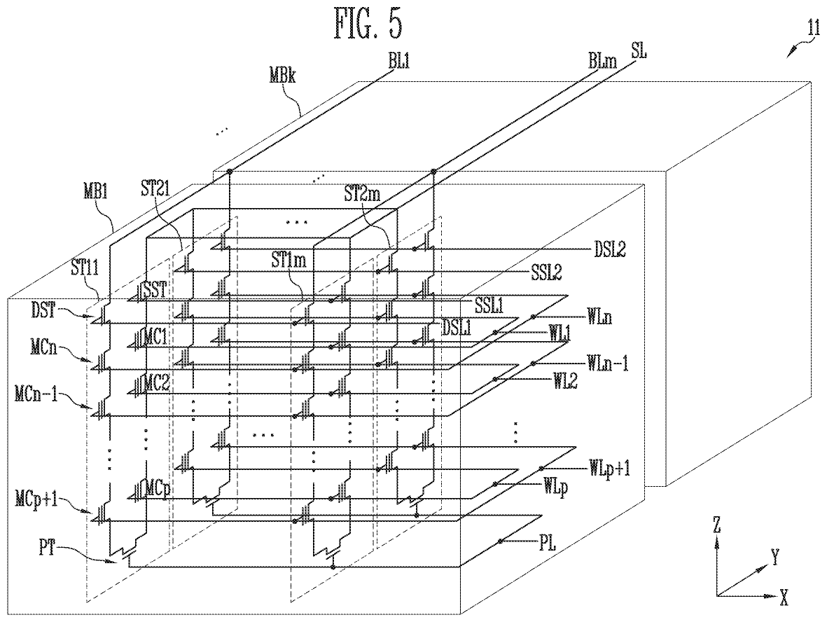

FIG. 5 is a diagram illustrating a memory block having a three-dimensional structure in accordance with an embodiment of the present disclosure.

Referring to FIG. 5, the memory cell array 10 may include a plurality of memory blocks MB1 to MBk (11). Each memory block 11 may include a plurality of strings ST11 to ST1m and ST21 to ST2m. In an embodiment, each of the strings ST11 to ST1m and ST21 to ST2m may be formed in a ‘U’ shape. In the first memory block MB1, m strings may be arranged in a row direction (i.e. an X direction). FIG. 5 illustrates that two strings are arranged in a column direction (i.e., a Y direction), but this is only an example. Three or more strings may be arranged in the column direction (the Y direction).

Each of the plurality of strings ST11 to ST1m and ST21 to ST2m may include at least one source select transistor SST, first to n-th memory cells MC1 to MCn, a pipe transistor PT, and at least one drain select transistor DST.

The source select transistor SST, the drain select transistor DST, and the memory cells MC1 to MCn may have structures similar to each other. For example, each of the source select transistor SST, the drain select transistor DST, and the memory cells MC1 to MCn may include a channel layer, a tunnel insulating layer, a charge trap layer, and a blocking insulating layer. For example, a pillar for providing the channel layer may be provided in each string. For instance, a pillar for providing at least one of the channel layer, the tunnel insulating layer, the charge trap layer, and the blocking insulating layer may be provided in each string.

The source select transistor SST of each string may be coupled between the source line SL and the memory cells MC1 to MCn.

In an embodiment, source select transistors of strings arranged in the same row may be coupled to a source select line extending in the row is direction. Source select transistors of strings arranged in different rows may be coupled to different source select lines. In FIG. 5, source select transistors of the strings ST11 to ST1m in a first row may be coupled to a first source select line SSL1. Source select transistors of the strings ST21 to ST2m in a second row may be coupled to a second source select line SSL2.

In an embodiment, the source select transistors of the strings ST11 to ST1m and ST21 to ST2m may be coupled in common to a single source select line.

The first to n-th memory cells MC1 to MCn in each string may be coupled between the source select transistor SST and the drain select transistor DST.

The first to n-th memory cells MC1 to MCn may be divided into first to p-th memory cells MC1 to MCp and p+1-th to n-th memory cells MCp+1 to MCn. The first to p-th memory cells MC1 to MCp may be successively arranged in a vertical direction (i.e., in a Z direction) and coupled in series to each other between the source select transistor SST and the pipe transistor PT. The p+1-th to n-th memory cells MCCp+1 to MCn may be successively arranged in the vertical direction (the Z direction) and coupled in series to each other between the pipe transistor PT and the drain select transistor DST. The first to p-th memory cells MC1 to MCp and the p+1-th to n-th memory cells MCp+1 to MCn may be coupled to each other through the pipe transistor PT. Gates of the first to n-th memory cells MC1 to MCn of each string may be respectively coupled to first to n-th word lines WL1 to WLn.

In an embodiment, at least one of the first to n-th memory cells MC1 to MCn may be used as a dummy memory cell. In the case where the dummy memory cell is provided, the voltage or the current of the corresponding string may be stably controlled. Gates of the pipe transistors PT of the respective strings may be coupled to a pipeline PL.

The drain select transistor DST of each string may be coupled between the corresponding bit line and the memory cells MCp+1 to MCn. Strings arranged in the row direction may be coupled to corresponding drain select lines extending in the row direction. The drain select transistors of the strings ST11 to ST1m in the first row may be coupled to a first drain select line DSL1. The drain select transistors of the strings ST21 to ST2m in the second row may be coupled to a second drain select line DSL2.

Strings arranged in the column direction may be coupled to corresponding bit lines extending in the column direction. In FIG. 5, the strings ST11 and ST21 in a first column may be coupled to a first bit line BL1. The strings ST1m and ST2m in an m-th column may be coupled to an m-th bit line BLm.

Among the strings arranged in the row direction, memory cells coupled to the same word line may form one page. For example, memory cells coupled to the first word line WL1 in the strings ST11 to ST1m of the first row may form a single page. Memory cells coupled to the first word line WL1 in the strings ST21 to ST2m of the second row may form another single page. When any one of the drain select lines DSL1 and DSL2 is selected, strings arranged in the corresponding row may be selected. When any one of the word lines WL1 to WLn is selected, a corresponding single page may be selected from the selected strings.

FIG. 6 is a diagram illustrating an example of a memory block having a three-dimensional structure in accordance with an embodiment of the present disclosure.

Referring to FIG. 6, the memory cell array 10 may include a plurality of memory blocks MB1 to MBk (110). Each memory block 11 may include a plurality of strings ST11′ to ST1m′ and ST21′ to ST2m′.

Each of the strings ST11′ to ST1m′ and ST21′ to ST2m′ may extend in a vertical direction (Le., in a Z direction). In each memory block 11, m strings may be arranged in a row direction (Le., in an X direction). FIG. 6 illustrates that two strings are arranged in a column direction (i.e., in a Y direction), but this is only an example. Three or more strings may be arranged in the column direction (the Y direction).

Each of the strings ST11′ to ST1m′ and ST21′ to ST2m′ may include at least one source select transistor SST, first to n-th memory cells MC1 to MCn, and at least one drain select transistor DST.

The source select transistor SST of each string may be coupled between the source line SL and the memory cells MC1 to MCn. Source select transistors of strings arranged in the same row may be coupled to the same source select line. The source select transistors of the strings ST11′ to ST1m′ arranged in a first row may be coupled to a first source select line SSL1. The source select transistors of the strings ST21′ to ST2m′ arranged in a second row may be coupled to a second source select line SSL2. In an embodiment, the source select transistors of the strings ST11′ to ST1m′ and ST21′ to ST2m′ may be coupled in common to a single source select line.

The first to n-th memory cells MC1 to MCn in each string may be coupled in series between the source select transistor SST and the drain select transistor DST. Gates of the first to nth memory cells MC1 to MCn may be respectively coupled to first to nth word lines WL1 to WLn.

In an embodiment, at least one of the first to n-th memory cells MC1 to MCn may be used as a dummy memory cell. In the case where the dummy memory cell is provided, the voltage or the current of the corresponding string may be stably controlled. Thereby, the reliability of data stored in each memory block 11 may be improved.

The drain select transistor DST of each string may be coupled between the corresponding bit line and the memory cells MC1 to MCn. Drain select transistors DST of strings arranged in the row direction may be coupled to corresponding drain select lines extending in the row direction. The drain select transistors DST of the strings ST11′ to ST1m′ in the first row may be coupled to a first drain select line DSL1. The drain select transistors DST of the strings ST21′ to ST2m′ in the second row may be coupled to a second drain select line DSL2.

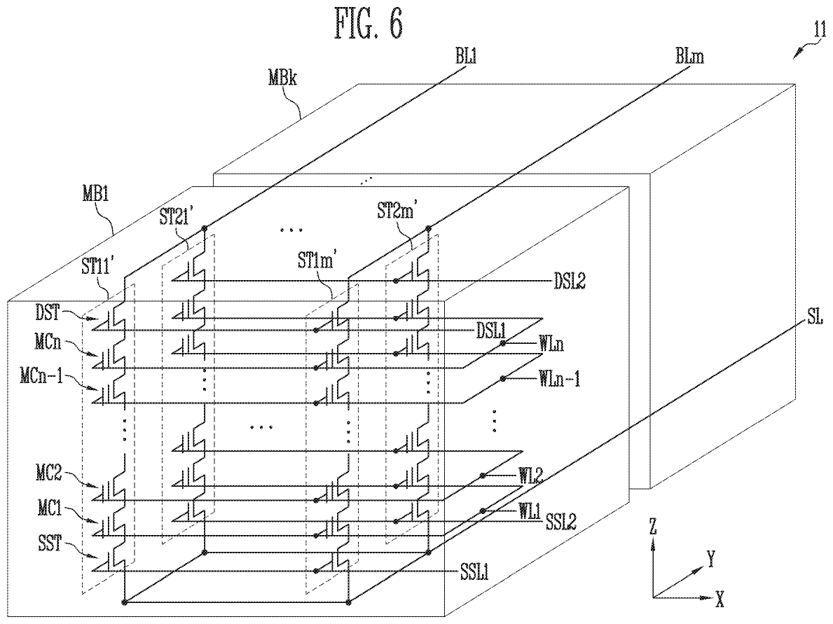

FIG. 7 is a flowchart illustrating an operation of the memory is system in accordance with an embodiment of the present disclosure. Such method is described below with additional reference to FIGS. 1 to 6.

The controller 1200 receives a host command Host_CMD corresponding to a read command from the host 1400 at step S710. The controller 1200 may receive a plurality of host commands Host_CMD from the host 1400. Hence, the controller 1200 may receive one or more read commands. For example, the controller 1200 may receive, from the host 1400, both a host command Host_CMD corresponding to a read command and an address ADD including a logical address of data to be read. In the case where a plurality of read commands are received, a plurality of addresses ADD corresponding to the respective read commands are also received.

The processor 1220 of the controller 1200 may generate a command queue corresponding to a read operation in response to the host command Host_CMD, and map a logical address of the received address ADD to a physical address. The flash control circuit 1250 may generate an internal command for controlling the read operation of the memory device 1100 in response to a command queue generated by the processor 1220, and transmit the internal command and the address including the mapped physical address to the memory device 1100.

The memory device 1100 performs the read operation at step S720 in response to the internal command CMD and the address ADD that are received from the controller 1200. For example, the memory device 1100 may perform a read operation on one or more is selected physical pages PPG of a selected memory block (e.g., at least one of the memory blocks MB1 to MBk) of a selected semiconductor memory among the plurality of semiconductor memories 100 included in the memory device 1100, and transmit read data to the controller 1200.

The memory buffer circuit 1230 of the controller 1200 may temporarily store the data received from the memory device 1100 in the read buffer 1233 before transmitting the data to the host 1400.

The processor 1220 generates an accumulated read count of the address on which the read operation has been completed (at step S730). That is, each time a read operation is completed for an associated address, the processor 1220 increments a count for that address, thereby generating an accumulated read count for that address. Here, the address may be an address, i.e., a logical address, received from the host 1400. If a plurality of read commands are received from the host 1400, respective accumulated read counts of a plurality of addresses may be generated, one for each address.

The accumulated read count of the address for which the read operation was completed is compared with the first set count “a” (at step S740).

If it is determined at step S740 that the accumulated read count of the address is greater than or equal to the first set count “a” (YES at step S740), information about the corresponding address is updated on the address list stored in the address list storage block 1231 of the memory buffer circuit 1230 at step S750.

If information about at least one address is added to the address list stored in the address list storage block 1231, the processor 1220 controls the memory buffer circuit 1230 and the host control circuit 1210 to transmit the address list to the host 1400 at step S760.

The host 1400 generates, based on the address information included in the received address list ADD_list, a new address ADD and a host command Host_CMD corresponding to a write operation for data corresponding to the address information at step S770, and transmits the new address ADD and the host command Host_CMD to the controller 1200. Here, the address ADD may be generated to have a new logical address based on the address information included in the address list ADD _list. Since the data for which the write operation is to be performed is received as a result of the last requested read operation based on a time at which the host 1400 has received the address list ADD_list, the data received to the host 1400 may be transmitted back to the controller 1200, or the controller 1200 may be controlled to perform the write operation using data remaining in the read buffer 1233 of the controller 1200.

The controller 1200 may receive the new address ADD and the host command Host_CMD corresponding to the write operation for the data. The processor 1220 of the controller 1200 may generate a command queue corresponding to a write operation in response to the host command Host_CMD, and map a new physical address to the new address ADD. Furthermore, when data is received from the host 1400, is the process 1220 may temporarily store the received data in the write buffer 1232 of the memory buffer circuit 1230.

The flash control circuit 1250 may generate an internal command CMD for controlling the write operation of the memory device 1100 in response to a command queue, and transmit, to the memory device 1100, the internal command CMD, the address ADD mapped with the physical address, and the data that has been received from the host 1400 and temporarily stored in the write buffer 1232 of the memory buffer circuit 1230, or the data remaining in the read buffer 1233 of the memory buffer circuit 1230.

The memory device 1100 receives the internal command CMD and the address ADD, and stores the data DATA in a new memory block (at step S780).

Consequently, data corresponding to an address the accumulated read count of which is greater than or equal to the first set count may be stored in a new memory block. Therefore, even if a read operation for the data is subsequently requested, a read reclaim operation is prevented from being performed because the read count of the new memory block is increased without increasing the read count of the memory block in which the data has been first stored.

If, as a result of the comparison operation at step S740, the accumulated read count of the address is less than the first set count “a” (NO at step S740), the read reclaim control block 1224 of the processor 1220 may increase and newly update the read count of the memory block of the memory device 1100 on which the read operation has been performed, and check the respective read counts of all of the memory blocks included in the memory device 1100.

The read reclaim control block 1224 determines whether a memory block the read count of which is greater than or equal to the second set count “b” is present at step S800.

As a result of the determination operation at step S800, if it is determined that the read count of each of the memory blocks is less than the second set count “b” (NO at step S800), the operation of the memory system 100 may be terminated.

If even one memory block has a read count that is greater than or equal to the second set count “b” is detected (YES at step S800), the read reclaim control block 1224 may generate a command queue for a read reclaim operation, and the flash control circuit 1250 may generate an internal command CMD in response to the command queue and transmits the internal command CMD to the memory device 1100.

The memory device 1100 performs, in response to the internal command CMD, a read reclaim operation on a detected memory block at step S810. The read reclaim operation may include an operation of copying and storing valid data stored in the detected memory block to a new memory block that has no data, and an operation of erasing the detected memory block.

As described above, in accordance with an embodiment of the present disclosure, before the read count of a memory block reaches the second set value, the accumulated read count of a read requested address is used and thus data corresponding to the address is stored in a new memory block. Therefore, a read reclaim operation may be prevented from being performed.

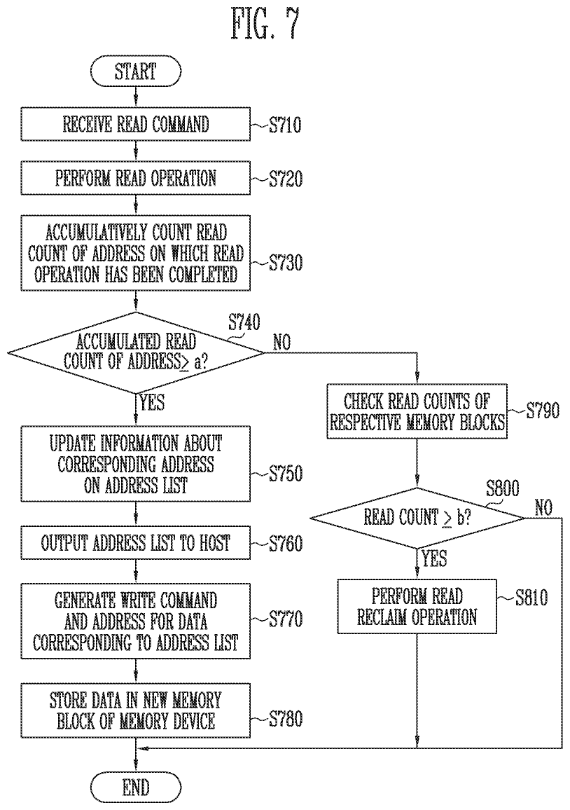

FIG. 8 is a diagram illustrating a controller 200 of FIG. 1 in accordance with an embodiment of the present disclosure.

Referring to FIG. 8, the controller 1200 may include a host control circuit 1210, a processor 1220, a memory buffer circuit 1230, an error correction circuit 1240, a flash control circuit 1250, and a bus 1260.

In the configuration of the controller 1200 according to this embodiment, the error correction circuit 1240, the flash control circuit 1250, and the bus 1260 may have the same configurations and operations as those of the embodiment described with reference to FIG. 2; therefore, further explanation thereof will be omitted.

The host control circuit 1210 may control data transmission between the host 1400 of FIG. 1 and the memory buffer circuit 1230. For example, the host control circuit 1210 may control an operation of buffering data input from the host 1400 to the memory buffer circuit 1230. In an embodiment, the host control circuit 1210 may control an operation of outputting data buffered in the memory buffer circuit 1230 to the host 1400.

The host control circuit 1210 may transmit a host command and an address which are received from the host 1400 to the processor 1220, or may transmit the address list stored in the memory buffer circuit 1230 to the host 1400 under control of the processor 1220.

The host control circuit 1210 may include an address read counter 1211 and an address list management block 1212.

The address read counter 1211 may count the number of times data associated with a particular address received from the host 1400 is read in a read operation and generate an accumulated count for such address. In other words, the address read counter 1211 may increase a previous accumulated read count of the address received from the host 1400 during the read operation by 1, and update the accumulated read count. The accumulated read count may be stored in the memory buffer circuit 1230.

When the accumulated read count of the address that is received from the host 1400 during the read operation, is greater than or equal to the first set count, the address list management block 1223 may update information about the address on the address list and store the updated address list in the memory buffer circuit 1212.

The host control circuit 1210 may further include a host interface.

The processor 1220 may control the overall operation of the controller 1200 and perform a logical operation. The processor 1220 may communicate with the host 1400 of FIG. 1 through the host control circuit 1210, and communicate with the memory device 1100 of FIG. 1 through the flash control circuit 1250. The processor 1220 may control the operation of the memory system 1000 by using the memory buffer circuit 1230 as an operation memory, a cache memory, or a buffer memory.

The processor 1220 may rearrange, based on priorities, a plurality of host commands received from the host 1400 and generate a command queue, and may control the flash control circuit 1250 based on the command queue. Furthermore, the processor 1220 may generate respective read counts of the plurality of memory blocks in the memory device 1100, and control the flash control circuit 1250 to perform a read reclaim operation on a memory block the read count of which is greater than or equal to the second set count. When a host command corresponding to a write operation for data that has been read during a latest read operation and remaining in the memory buffer 1230 is received from the host 1400, the processor 1220 may control the flash control circuit 1230 to transmit the data remaining in the read buffer 1233 of the memory buffer circuit 1230 to the memory device 1100 and program the data to the memory device 1100.

The processor 1220 may include a flash translation layer (FTL) 1221, and a read reclaim control block 1224.

The FTL 1221 may drive firmware. The firmware may be stored in an additional memory (not illustrated) directly coupled to the buffer memory 1230 or the processor 1220, or may be stored in a storage space defined in the processor 1220. During a write operation, the FTL 1221 may map a physical address corresponding to an address (e.g., a logical address) input from the host 1400 of FIG. 1. Furthermore, during a read operation, the FTL 1221 may check a physical address mapped to a logical address input from the host 1400.

The FTL 1221 may generate a command queue for controlling the flash control circuit 1250 in response to a host command received from the host 1400.

The read reclaim control block 1224 may manage the respective read counts of the plurality of memory blocks included in the semiconductor memories 100 of the memory device 1100 of FIG. 1, and control the flash control circuit 1250 to perform a read reclaim operation on a memory block, the read count of which is greater than or equal to the second set count, among the plurality of memory blocks.

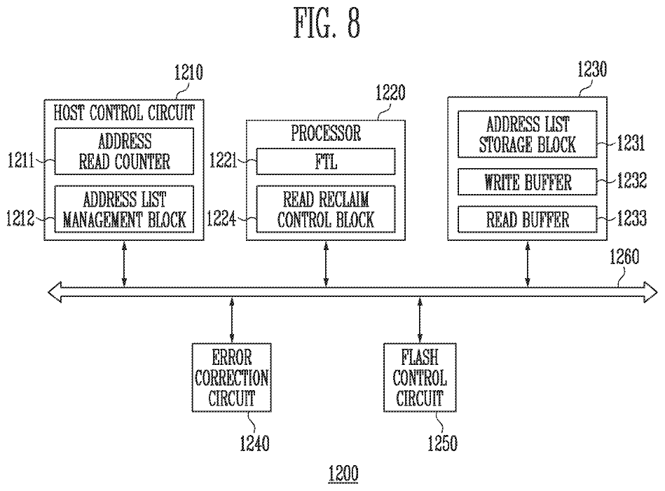

FIG. 9 is a diagram illustrating a memory system 30000 in accordance with an embodiment of the present disclosure.

Referring to FIG. 9, the memory system 30000 may be embodied in a cellular phone, a smartphone, a tablet PC, a personal digital assistant (PDA) or a wireless communication device. The memory system 30000 may include a memory device 1100, and a controller 1200 capable of controlling the operation of the memory device 1100. The controller 1200 may control a data access operation, e.g., a program operation, an erase operation, or a read operation, of the memory device 1100 under control of a processor 3100.

Data programmed to the memory device 1100 may be output through a display 3200 under control of the controller 1200.

A radio transceiver 3300 may send and receive radio signals through an antenna ANT. For example, the radio transceiver 3300 may convert a radio signal received through the antenna ANT into a signal capable of being processed in the processor 3100. Therefore, the processor 3100 may process a signal output from the radio transceiver 3300 and transmit the processed signal to the controller 1200 or the display 3200. The controller 1200 may program a signal processed by the processor 3100 to the memory device 1100. Furthermore, the radio transceiver 3300 may convert a signal output from the processor 3100 into a radio signal, and output the changed radio signal to an external device through the antenna ANT. An input device 3400 may be used to input a control signal for controlling the operation of the processor 3100 or data to be processed by the processor 3100. The input device 3400 may be embodied in a pointing device such as a touch pad and a computer mouse, a keypad or a keyboard. The processor 3100 may control the operation of the display 3200 such that data output from the memory controller 1200, data output from the radio transceiver 3300, or data output form the input device 3400 is output through the display 3200.

In an embodiment, the controller 1200 capable of controlling the operation of the memory device 1100 may be embodied as a part of the processor 3100 or a chip provided separately from the processor 3100. Furthermore, the controller 1200 may be embodied using an example of the controller illustrated in FIG. 2 or 8.

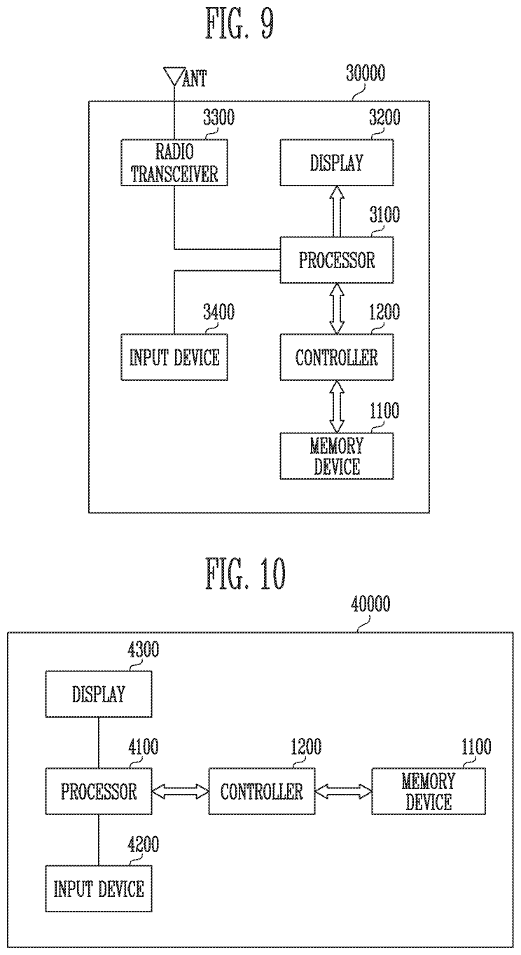

FIG. 10 is a diagram illustrating a memory system 40000 in accordance with an embodiment of the present disclosure.

Referring to FIG. 10, the memory system 40000 may be embodied in a personal computer (PC), a tablet PC, a net-book, an e-reader, a personal digital assistant (PDA), a portable multimedia player (PMP), an MP3 player, or an MP4 player.

The memory system 40000 may include a memory device 1100, and a controller 1200 capable of controlling a data processing operation of the memory device 1100.

A processor 4100 may output data stored in the memory device 1100 through a display 4300, according to data input from an input device 4200. For example, the input device 4200 may be embodied in a pointing device such as a touch pad or a computer mouse, a keypad, or a keyboard.

The processor 4100 may control the overall operation of the memory system 40000 and control the operation of the controller 1200. In an embodiment, the controller 1200 capable of controlling the operation of the memory device 1100 may be embodied as a part of the processor 4100 or a chip provided separately from the processor 4100. Furthermore, the controller 1200 may be embodied using an example of the controller illustrated in FIG. 2 or 8.

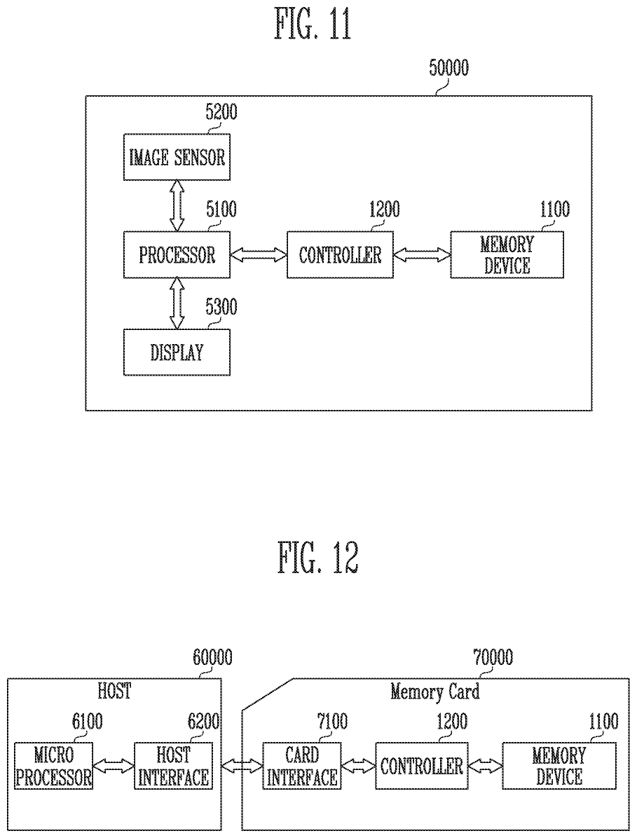

FIG. 11 is a diagram illustrating a memory system 50000 in accordance with an embodiment of the present disclosure.

Referring to FIG. 11, the memory system 50000 may be embodied in an image processing device, e.g., a digital camera, a portable phone provided with a digital camera, a smartphone provided with a digital camera, or a tablet PC provided with a digital camera.

The memory system 50000 may include a memory device 1100, and a controller 1200 capable of controlling a data processing operation, e.g., a program operation, an erase operation, or a read operation, of the memory device 1100.

An image sensor 5200 of the memory system 50000 may convert an optical image into digital signals. The converted digital signals may be transmitted to a processor 5100 or the controller 1200. Under control of the processor 5100, the converted digital signals may be output through a display 5300 or stored to the memory device 1100 through the controller 1200. Data stored in the memory device 1100 may be output through the display 5300 under control of the processor 5100 or the controller 1200.

In an embodiment, the controller 1200 capable of controlling the operation of the memory device 1100 may be embodied as a part of the processor 5100 or a chip provided separately from the processor 5100. Furthermore, the controller 1200 may be embodied using an example of the controller illustrated in FIG. 2 or 8.

FIG. 12 is a diagram illustrating a memory system 70000 in accordance with an embodiment of the present disclosure.

Referring to FIG. 12, the memory system 70000 may be embodied in a memory card or a smart card. The memory system 70000 may include a memory device 1100, a controller 1200, and a card interface 7100.

The memory controller 1200 may control data exchange between the memory device 1100 and the card interface 7100. In an embodiment, the card interface 7100 may be a secure digital (SD) card interface or a multi-media card (MMC) interface, but it is not limited thereto. Furthermore, the controller 1200 may be embodied using an example of the controller illustrated in FIG. 2 or 8.

The card interface 7100 may interface data exchange between a host 60000 and the controller 1200 according to a protocol of the host 60000. In an embodiment, the card interface 7100 may support a universal serial bus (USB) protocol, and an interchip (IC)-USB protocol. Here, the card interface may refer to hardware capable of supporting a protocol which is used by the host 60000, software installed in the hardware, or a signal transmission scheme.

When the memory system 70000 is connected to a host interface 6200 of the host 60000 such as a PC, a tablet PC, a digital camera, a digital audio player, a cellular phone, console video game hardware or a digital set-top box, the host interface 6200 may perform data communication with the memory device 1100 through the card interface 7100 and the controller 1200 under control of a microprocessor 6100.

In various embodiments of the present disclosure, an address of data to which a read request is received may be counted each time such read request is received to generate an accumulated count, and a write operation for the read data is performed when the accumulated count is greater than or equal to a set count. Therefore, the read count of a memory block is prevented from being excessively increased, whereby a read reclaim count may be efficiently managed. As a result, the number of times a read reclaim operation is required to be performed may be reduced. Consequently, the efficiency of a memory system may be improved.

Although embodiments of the present disclosure have been disclosed, those skilled in the art will appreciate in light of the present disclosure that various modifications, additions and substitutions are possible, without departing from the scope and spirit of the present invention.

Therefore, the scope of the present invention is defined by the appended claims and equivalents thereof rather than by the description preceding them.

In the above-discussed embodiments, steps may be selectively performed or skipped. In addition, the steps in each embodiment may not be always performed in regular order. Furthermore, the embodiments disclosed herein aim to help those with ordinary knowledge in this art more clearly understand the present invention rather than aiming to limit the bounds of the present invention.

In describing embodiments of the present disclosure, specific terms or words used should be construed in accordance with the spirit of the present invention without limiting the subject matter thereof. It should be understood that many variations and modifications of the basic inventive concept described herein will still fall within the spirit and scope of the present invention as defined in the appended claims and their equivalents.

What is claimed is:

1. A memory system comprising:
a host configured to transmit a read command and an address and request a read operation;
a controller configured to generate an internal command corresponding to the read operation in response to the read command and the address, and generate an accumulated read count of the address on which the read operation has been completed; and
a memory device configured to perform the read operation in response to the internal command and transmit data read by performing the read operation to the controller,
wherein the controller receives the read data from the memory device, temporarily stores the read data, and then transmits the read data to the host, and generates an address list including information about the address when the accumulated read count of the address is greater than or equal to a set count.

2. The memory system according to claim 1,
wherein the controller transmits the address list to the host, and
wherein the host requests a write operation for the read data based on the address list received from the controller.

3. The memory system according to claim 2, wherein the host generates a new address different from the address based on the information about the address included in the address list, and transmits the new address and a write command to the controller.

4. The memory system according to claim 3, wherein the host transmits, to the controller, the read data that is last received with reference to a time at which the address list is received.

5. The memory system according to claim 4, wherein the controller generates the internal command for the write operation in response to the write command and the new address that are received from the host, and controls the memory device such that the read data received from the host is stored in the memory device.

6. The memory system according to claim 3, wherein the controller generates the internal command for the write operation in response to the write command and the new address that are received from the host, and controls the memory device such that the read data remaining in the controller during the read operation is stored in the memory device.

7. The memory system according to claim 1, wherein the controller comprises:
a processor;
an address read counter configured to generate the accumulated read count of the address; and
an address list management block configured to compare the accumulated read count of the address with the set count and generate the address list.

8. The memory system according to claim 7, wherein the controller further comprises a memory buffer circuit comprising:
a read buffer configured to temporarily store the read data received from the memory device during the read operation; and
an address list storage block configured to store the accumulated read count of the address and the address list.

9. The memory system according to claim 8, wherein, when the write command received from the host is received, the controller transmits the read data stored in the read buffer to the memory device.

10. A memory system comprising:
a controller configured to generate an internal command corresponding to a read operation in response to a read request and an address that are received from a host, and generate an accumulated read count of the address on which the read operation has been completed; and
a memory device configured to perform the read operation in response to the internal command and transmit data read by performing the read operation to the controller,
wherein the controller controls the memory device such that, when the accumulated read count of the address is greater than or equal to a first set count, the read data received from the memory device is stored in a new memory block of the memory device.

11. The memory system according to claim 10, wherein, when the accumulated read count is greater than or equal to the first set count, the controller generates an address list including information about the address and outputs the address list to the host.

12. The memory system according to claim 10, wherein the controller comprises:
a processor;
an address read counter configured to generate the accumulated read count of the address;
an address list management block configured to compare the accumulated read count of the address with the first set count and generate the address list; and
a read reclaim control block configured to generate respective read counts of memory blocks included in the memory device and manage the read counts, and control a read reclaim operation based on the read counts.

13. The memory system according to claim 12, wherein the read reclaim control block controls the memory device to perform the read reclaim operation on a memory block the read count of which is greater than or equal to a second set count.

14. The memory system according to claim 12, wherein the controller further comprises a memory buffer circuit comprising:
a read buffer configured to temporarily store the read data received from the memory device during the read operation; and
an address list storage block configured to store the accumulated read count of the address and the address list.

15. A method of operating a memory system, comprising:
receiving a read command and an address from a host;
performing a read operation of a memory device in response to the read command and the address;
temporarily storing data read as a result of the read operation in a controller, and transmitting the read data to the host;
generating an accumulated read count of the address, and comparing the accumulated read count with a first set count; and
generating, when the accumulated read count is greater than or equal to the first set count as a result of the comparing, an address list including information about the address, and transmitting the address list to the host.

16. The method according to claim 15, further comprising:
generating a write command and a new address for the read data based on the address list received from the controller; and
performing a write operation for the read data in response to the write command and the new address.

17. The method according to claim 16, wherein the write operation is performed on a new memory block of the memory device.

18. The method according to claim 16, wherein the controller receives the read data along with the write command and the new command from the host, transmits the received read data to the memory device, and performs the write operation.

19. The method according to claim 16, wherein, when the write command and the new command are received, the controller transmits the read data remaining therein to the memory device, and performs the write operation.

20. The method according to claim 15, further comprising, when the accumulated read count is less than the first set count as a result of the comparing:
comparing respective read counts of all memory blocks included in the memory device with a second set count; and
performing a read reclaim operation on a memory block the read count of which is greater than or equal to the second set count.
